(19) United States
(12) Patent Application Publication
(10) Pub. No.: US 2003/0212949 A1
(43) Pub. Date: Nov. 13, 2003

(54) Apparatus for back-tracking survivor paths of trellis code data and method thereof

(76) Inventor: Jai-Seung Noh, Ichon-shi (KR)

Correspondence Address: BIRCH STEWART KOLASCH & BIRCH, PO BOX 747, FALLS CHURCH, VA, 22040-0747, US

(21) Appl. No.: 10/331,992

(22) Filed: Dec. 31, 2002

(30) Foreign Application Priority Data
May 10, 2002 (KR) 2002-25774

(51) Int. Cl. H03M 13/03

(52) U.S. Cl. 714/792

(57) ABSTRACT

A backtracking apparatus and method for adaptively control a threshold time is disclosed. The present invention, for backtracking survivor paths for trellis code data, wherein the trellis decoder has a trellis diagram, including: a tracking unit for backtracking a set of survivor path during a predetermined threshold time; a storage unit for storing a previous set of survivor paths; a determination unit for determining whether or not the previous set of survivor paths are converged a node to generate a convergence signal representing whether or not converging; a control unit for controlling the threshold time and response to the convergence signal to thereby backtracking the survivor paths during a controlled threshold time. The present invention can increase a performance of a system using the viterbi decoder and decrease processing time by adaptively controlling the threshold time when backtracking a trellis code data.

### FIELD OF THE INVENTION

The present invention relates to a viterbi decoder; and, more particularly, to a backtracking block of the viterbi decoder in a quadrature phase shift keying (QPSK) integrated circuit (IC) for digital video broadcasting (DVB)/digital subscriber signaling (DSS).

### DESCRIPTION OF RELATED ARTS

Generally, a convolution encoder and a viterbi decoder have been used for error control and correction in a digital communication system.

FIG. 1 is a diagram showing a conventional convolution encoder. The convolution encoder is used at a transmitter. The convolution encoder encodes data for error correction and after generating encoded data, the encoded data is transmitted to a decoder in a receiver.

Referring to FIG. 1, the convolution encoder includes a 2-bit shift register 11 and two adder 12 and 12′ for performing modulo-2 addition. The convolution encoder determines one of output G1 and G2 according to a state of the shift register 11 and an input 13. An output state according to time is shown in FIG. 2.

FIG. 2 is a trellis diagram for explaining an output state of a convolution encoder according to time.

Referring to FIG. 2, each of nodes in the trellis diagram represents a state of a shift register in FIG. 1. Branches of solid line show transition when input is 0 and branches of dotted line depict transition when input is 1. Numbers on branches represents output value G1 or G2 when transition of corresponding branch is occurred. As shown in FIG. 2, two paths of each state are finally converged at one node. Based on this characteristic, a viterbi decoder in a receiver selects one of the two paths according to a viterbi algorithm. The selected path is called a survivor path and the receiver maintains information regarding to the survivor path as much as a decision depth or a truncation depth.

Therefore, the viterbi decoder decodes the encoded data from the transmitter by backtracking the survivor paths of each state.

FIG. 3 is a diagram illustrating a conventional trellis decoder. The trellis decoder implements the viterbi algorithm for decoding.

Referring to FIG. 3, the trellis decoder includes: a branch metric calculator 22 for calculating likelihood between reference values of each branch in the trellis diagram and received input signal 21; an add-compare-select (ACS) calculator 23 for selecting a survivor path of each state and calculating state metric of the survivor path; a regulator 24 for subtracting a maximum likelihood value from a result of the ACS calculator 23; a state value storage 25 for storing the state value; a maximum likelihood value detector 26 for selecting one of survivor paths of each state; a path storage 27 for storing information of selected survivor path, and a backtracker 28 for performing backtracking according to outputs of the path storage 27 and the maximum likelihood value detector 26.

FIG. 4 is a diagram depicting the backtracker 28 in FIG. 3. The backtracker 28 includes a path memory 31 for storing survivor paths as many as decision depth, a multiplexer 32 and a register 33. A size of register 33 is same with {K(constraint length)−1}, a size of the path memory is {M(=2 K−1)*L(decision depth)} and the multiplexer 32 is M:1 multiplexer.

As mentioned above, the trellis decoder backtracks the survivor paths for a predetermined time based on information of survivor path of each time unit.

That is, when the information of survivor path smⱼ of a state mⱼ−aⱼbⱼ at a time unit j, the state at a time unit j−1 is mⱼ−1=aⱼ₋₁bⱼ₋₁ is mⱼ₋₁=bⱼsmⱼ. Since bⱼ=aⱼ₋₁ and smⱼ=bⱼ−1 is known to the convolution encoder, the convolution encoder detects a state with a minimum value at each time unit. Based on the minimum value and the information of the survivor path from the path memory 31, the previous state is determined. Above mentioned steps are reputedly performed as many as decision depth, that is permitted total tracking time.

As mentioned above, the viterbi decoder uses convergence characteristic of trellis code for error correction. The viterbi decoder completes the backtracking of the survivor paths after the survivor paths are converged at one node.

A time for backtracking the survivor paths to detect the convergence is variable. Therefore, the time for backtracking is predetermined and set as a threshold time and the conventional viterbi decoder completes the backtracking of the survivor paths before the threshold time is exceeded.

FIG. 5 is a graph showing a case of failing to detect the convergence of the survivor paths in the predetermined threshold time.

Referring to FIG. 5, a decision depth is 128, the predetermined threshold time is set to 60. If the survivor paths are converged before the threshold time 60, the backtracking of the viterbi decoder is not failed. However, in FIG. 5, the survivor paths are converged after the predetermined threshold time. Therefore, the conventional viterbi decoder is failed to detect the convergence of the survivor paths because of the predetermined threshold time.

As mentioned above, the conventional viterbi decoder cannot adaptively control the threshold time for backtracking the survivor paths, therefore, the conventional viterbi decoder cannot detects the convergence of the survivor paths, if the survivor paths are converged after exceeding the predetermined and fixed threshold time. Also, if the survivor paths are converged before exceeding the predetermined and fixed threshold time, it may waste processing time.

### SUMMARY OF THE INVENTION

It is, therefore, an object of the present invention to provide a backtracking apparatus and method for adaptively control a threshold time in order to increase a system performance and decrease a processing time.

In accordance with an aspect of the present invention, there is also provided an apparatus, for use in a trellis decoder, for backtracking survivor paths for trellis code data, wherein the trellis decoder has a trellis diagram including a plurality of survivor paths and a number of nodes, including: a tracking unit for backtracking a set of survivor path during a predetermined threshold time; a storage unit for storing a previous set of survivor paths; a determination unit for determining whether or not the previous set of survivor paths are converged a node to generate a convergence signal representing whether or not converging; a control unit for controlling the threshold time and response to the convergence signal to thereby backtracking the survivor paths during a controlled threshold time.

In accordance with an aspect of the present invention, there is also provided a method, for use in a trellis decoder, for backtracking survivor paths for trellis code data, wherein the trellis decoder has a trellis diagram including a plurality of survivor paths and a number of nodes, including the steps of: a) backtracking a set of survivor path during a predetermined threshold time; b) determining whether or not the previous set of survivor paths are converged a node; and c) generating a controlled threshold time according to a result of step b) to optimize operations in step a).

### BRIEF DESCRIPTION OF THE DRAWING(S)

The above and other objects and features of the present invention will become apparent from the following description of the preferred embodiments given in conjunction with the accompanying drawings, in which:

FIG. 1 is a diagram showing a conventional convolution encoder;

FIG. 2 is a trellis diagram for explaining an output state of a convolution encoder;

FIG. 3 is a diagram illustrating a conventional trellis decoder;

FIG. 4 is a diagram depicting the backtracker 28 in FIG. 3;

FIG. 5 is a graph showing a case of failing to detect the convergence of the survivor paths in the predetermined threshold time;

FIG. 6 is a diagram illustrating an apparatus for backtracking survivor paths of trellis code data in accordance with a preferred embodiment of the present invention;

FIGS. 7 to 9 are graphs showing steps of backtracking a convergence node of survivor paths and corresponding threshold times for explaining operations of the present invention; and

FIG. 10 is a flowchart explaining operations of backtracking apparatus in accordance with a preferred embodiment of the present invention.

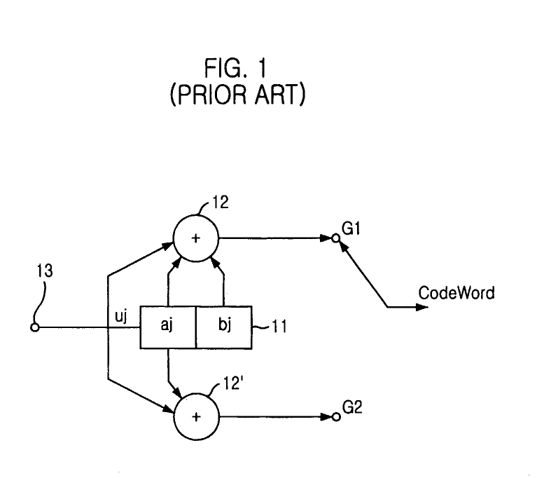

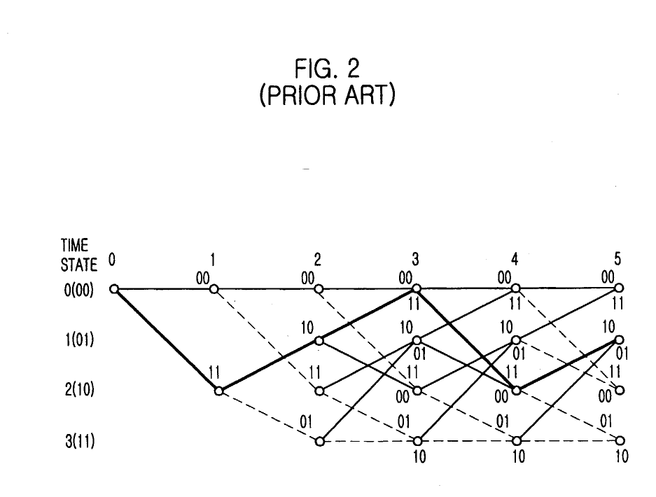

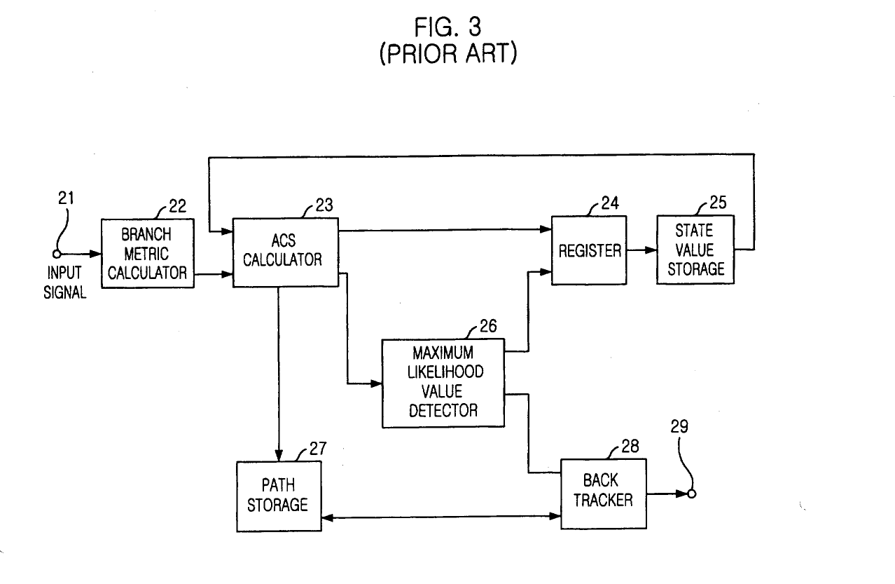

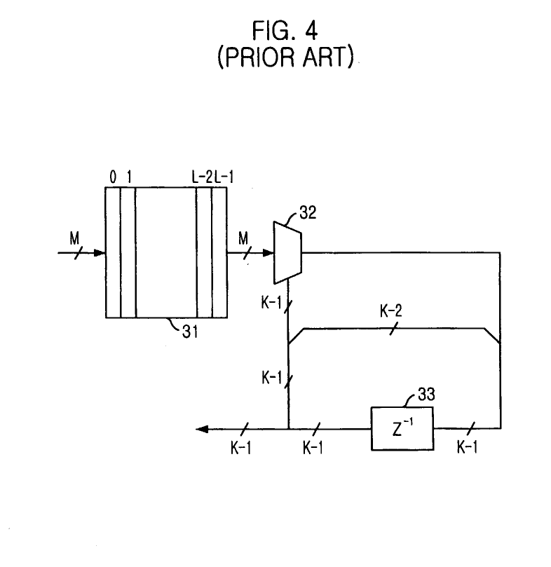

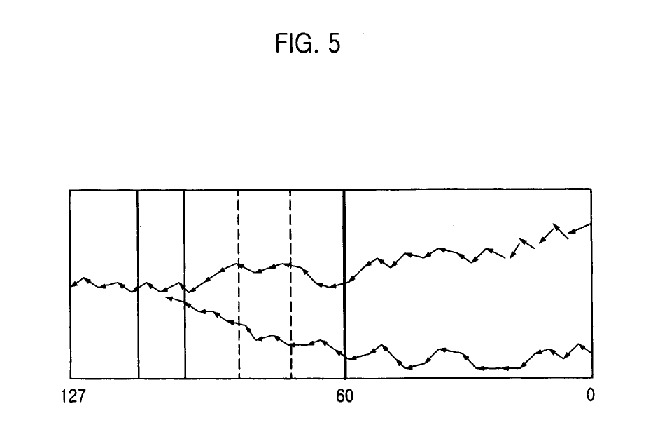

### DETAILED DESCRIPTION OF THE INVENTION

Other objects and aspects of the invention will become apparent from the following description of the embodiments with reference to the accompanying drawings, which is set forth hereinafter.

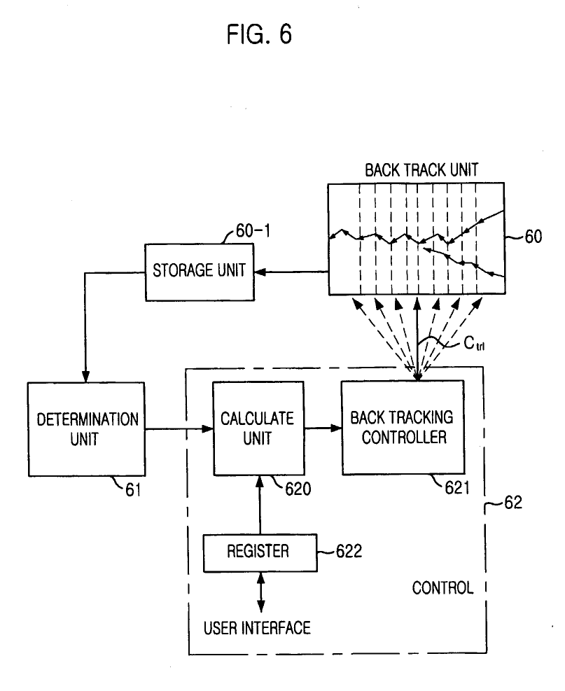

FIG. 6 is a diagram illustrating an apparatus for backtracking survivor paths of trellis code data in accordance with a preferred embodiment of the present invention.

Referring to FIG. 6, the apparatus includes a back track unit 60, a storage unit 60-1, a determination unit 61 and a controller 62.

The back track unit 60 back tracks a set of survivor paths for a predetermined threshold time.

The storage unit 60-1 stores a result of backtracking and information of a previous set of the survivor paths.

The determination unit 61 determines whether or not the survivor paths are converged while the survivor paths are back tracked during the predetermined threshold time and generates a convergence signal. The convergence signal includes a first convergence signal and a second convergence. The first convergence signal represents the survivor paths are converged during the predetermined threshold time and the second convergence signal represents the survivor paths are not converged during the predetermined threshold time.

The controller 62 adaptively controls a threshold time for optimizing backtracking operation in the back track unit 60 by receiving the convergence signal from the determination unit 61. Duration of back tracking duration is controlled by increasing or decreasing the threshold time. The controller 62 increases the threshold time by one unit time in case of the first convergence signal is received. That is, if the survivor paths are not converged after back tracking the survivor paths for the predetermined threshold time, the controller increases the threshold time. In contrast, if the survivor paths are converged before the threshold time is exceeded, the controller 62 decreases the threshold time by one unit time. The threshold time is a sum of multiple unit times. For example, if the unit time is operated by being synchronized with a rising edge of a system clock, the unit time is identical to a cycle of the system clock. The unit time is controllable by a user and the threshold time may not exceed the predetermined threshold time.

The controller 62 further includes a calculate unit 620, a back track controller 621 and a register 622.

The register 622 receives an amount of a threshold time to be controlled by a user through a user interface and generates a user control signal representing the amount of threshold time to be controlled. By the register 622, the user can control the threshold time to optimize back tracking of the survivor paths.

The calculate unit 620 calculates an amount of a threshold time to be controlled according to the convergence signal and the user control signal. The calculate unit 620 performs a up-counting, if the survivor paths are not converged after the threshold time is exceeded and performs a down-counting, if the survivor paths are converged before the threshold time is not exceeded. After calculating, the calculate unit 620 generates a controllable time signal.

The back track controller 621 controls the threshold time according to the controllable time signal. According to the controllable time signal, the back track controller generate a controlled threshold time. The controlled threshold time is a threshold time for optimizing operations of back tracking the set of survivor paths.

As mentioned above, the present invention provides a way of adaptively changing the threshold time for overcoming conventional problems caused by a fixed threshold time for backtracking.

For overcoming the conventional problems, the present invention additionally includes the controller 62 containing the calculate unit 620, the back track controller 621 and the register 622.

At an initial mode, the threshold time is predetermined and assigned to the back track unit 61, however, the threshold time is adaptively changed according to a previous result of the backtracking. The calculate unit 620 counts controllable variable amount of the threshold time after the convergence of the survivor paths is failed. The back track controller 621 generates the control signal (Ctrl) for controlling the threshold time according to a result of the calculate unit 620. The register 623 receives an amount of the threshold time to be controlled from a user through a user interface.

In a meantime, if the present invention is implemented as a hardware circuit, a size of the controller 62 may be very small and in the convergence detector 61, simple control logic is additional equipped.

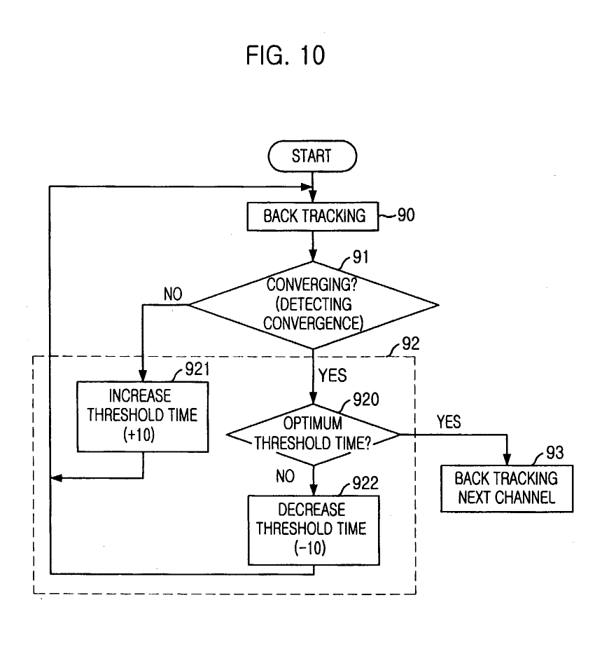

Operations of the present invention are explained in below as referring to FIG. 10.

FIG. 10 is a flowchart explaining operations of backtracking apparatus in accordance with a preferred embodiment of the present invention.

Referring to FIG. 10, survivor paths are backtracked for a threshold time, which is predetermined at the initial mode at step 90. After exceeding the threshold time, convergence of the survivor paths are determined at step 91, if the survivor paths are converged, the threshold time is changed for optimizing the backtracking step 90. After changing the threshold time, next backtracking operation is performed at step 93.

As mentioned above backtracking steps, the threshold time is reputedly changed by adding or subtracting a unit time in order for finding optimum threshold time. If the survivor paths are not converged for the threshold time, the threshold time is increased within one unit time and fined optimum threshold value at step 921.

If the survivor paths are converged, the threshold time is analyzed for optimizing the threshold time at step 920. If it is analyzed as an optimum threshold time, another backtracking is performed at step 93, and if it is not, the threshold time is changed by subtracting one unit time from the threshold time at step 922. Therefore, the present invention can decrease a processing time by finding the optimum threshold time.

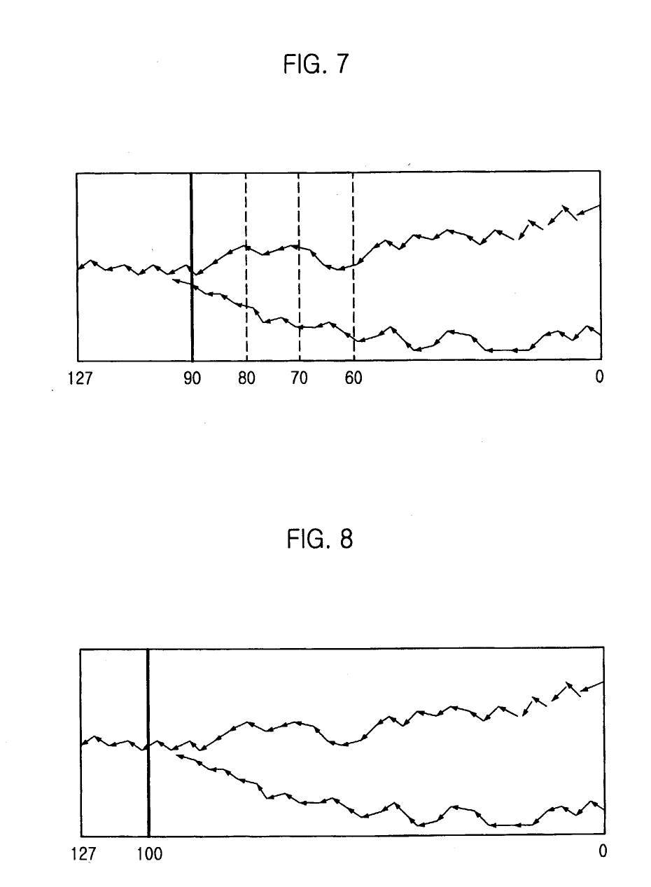

FIGS. 7 to 9 are graph showing steps of backtracking a convergence node of survivor paths and corresponding threshold times for explaining operations of the present invention.

The present invention uses a fact that a noise increases a time for converging survivor paths.

If a signal is seriously affected by the noise, the convergence of the survivor paths will take longer time than an initial threshold time.

Referring to FIG. 7, an initial threshold time is 60 and a threshold time is increased by 10 unit time in a cycle of the backtracking operations. Finally, the threshold time is reset to 90 in four cycles of operation steps of the present invention (60→70→80→90). A decision depth is 128 as shown in FIG. 7. At the initial threshold time ‘60’, the survivor paths are not converged at a first cycle of operation steps of the present invention. It is detected by a convergence detector 61 in the present invention and the threshold time is reset as 70 by the controller 62. The convergence of the survivor paths are analyzed after exceeding the reset threshold time ‘70’ by the convergence detector 61. If the survivor paths are not converged, the threshold time is increased by a unit time ‘10’ and the convergence of the survivor paths is re-analyzed. The threshold time is reset to 90 in FIG. 7 but the survivor paths are not converged. As shown in FIG. 8, the survivor paths are converged before newly reset threshold time 100 is not exceeded.

As shown in FIG. 7 and 8, the present invention increases the threshold time in one unit time in every cycle for detecting the convergence of the survivor paths.

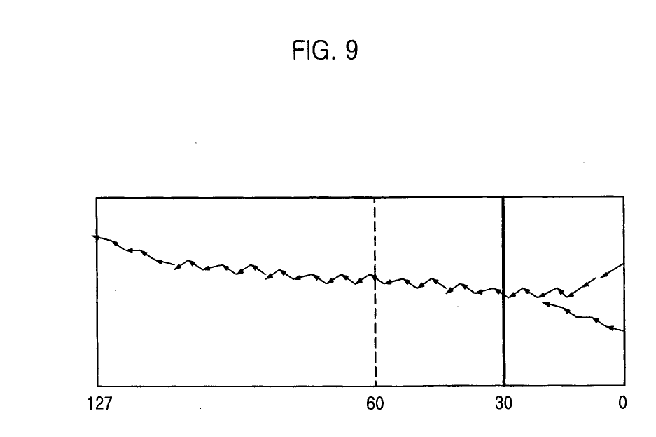

In contrast, if the survivor paths are converged before the threshold time is not exceeded, then the present invention decreases the threshold time by one unit time. FIG. 9 shows a case of the survivor paths are converged before the threshold time is not exceeded. In this case, if the initial threshold time is set as 60, the threshold time is decreased by one unit time for eliminating a processing redundancy.

In a meantime, a variation amount of the threshold time such as the unit time 10 in FIGS. 7 and 8 can be set by a user.

As mentioned above, the present invention adaptively controls the threshold time according to a previous result from convergence of the survivor paths. By adaptively controlling the threshold time, an acquisition performance is increased since a fail of the backtracking caused by too short threshold time is improved. The present invention also provides a way of controlling the threshold time at a system level. As a result, the acquisition performance can be controlled by a user through a control device such as a set top box.

The present invention is explained by using above mentioned preferred embodiment in a quadrature phase shift keying (QPSK) integrated circuit (IC) for digital video broadcasting (DVB)/digital subscriber signaling (DSS). However, the present invention can be used in any device using a viterbi decoder such as a hard disk, a satellite receiver, a digital Television and a Modem.

The present invention can increase a performance of a system using the viterbi decoder and decrease processing time by adaptively controlling the threshold time when backtracking a trellis code data.

While the present invention has been described with respect to certain preferred embodiments, it will be apparent to those skilled in the art that various changes and modifications may be made without departing from the scope of the invention as defined in the following claims.

What is claimed is:

1. An apparatus, for use in a trellis decoder, for backtracking survivor paths for trellis code data, wherein the trellis decoder has a trellis diagram including a plurality of survivor paths and a number of nodes, comprising:
a tracking unit for backtracking a set of survivor path during a predetermined threshold time;
a storage unit for storing a previous set of survivor paths;
a determination unit for determining whether or not the previous set of survivor paths are converged a node to generate a convergence signal representing whether or not converging;
a control unit for controlling the threshold time and response to the convergence signal to thereby backtracking the survivor paths during a controlled threshold time.

2. The apparatus as recited in claim 1, wherein the convergence signal includes a first convergence signal representing that the survivor paths are converged on a node, and the control unit, in response to the first convergence signal, controls the threshold time to thereby increase the threshold time by a predetermined value.

3. The apparatus as recited in claim 1, wherein the convergence signal includes a second convergence signal representing that the survivor paths are not converged on a node, and the control unit, in response to the second convergence signal, controls the threshold time to thereby decrease the threshold time by a predetermined value.

4. The apparatus as recited in the claim 2, wherein the predetermined value is integer number times of a system clock cycle.

5. The apparatus as recited in the claim 2, wherein the threshold time is not exceed a permitted total tracking time.

6. The apparatus as recited in the claim 1, wherein the control unit includes:
a register for receiving an amount of threshold time to be controlled from a user through a user interface in order to generate a user control signal;
a calculate unit for calculating an amount of the threshold time to be controlled according to the convergence signal and the user control signal in order to generate a controllable time signal; and
a backtrack controller for controlling the threshold time according to the controllable time signal in order to generate the controlled threshold time.

7. The apparatus as recited in claim 6, wherein the calculate unit calculates the amount of threshold time to be controlled by performing a up-counting operation when the first convergence signal is inputted and calculates the amount of threshold time to be controlled by performing a down-counting operation when the second convergence signal is inputted.

8. A method, for use in a trellis decoder, for backtracking survivor paths for trellis code data, wherein the trellis decoder has a trellis diagram including a plurality of survivor paths and a number of nodes, comprising the steps of:
a) backtracking a set of survivor path during a predetermined threshold time;
b) determining whether or not the previous set of survivor paths are converged a node; and
c) generating a controlled threshold time according to a result of step b) to optimize operations in step a).

9. The method as recited in claim 8, wherein the step c) reputedly changes the predetermined threshold time in order to compute a controlled threshold time.

10. The method as recited in claim 9, wherein the predetermined threshold time is increased as much as one unit time in order to generate the controlled threshold time when the survivor paths are not converged.

11. The method as recited in claim 9, wherein the predetermined threshold time is decreased as much as one unit time in order to generate the controlled threshold time when the survivor paths are converged.

12. The method as recited in claim 9, wherein the one unit time is integer number times of a system clock cycle.

13. The method as recited in claim 9, wherein the threshold time is not exceeded a permitted total tracking time.
